(19) United States
(12) Patent Application Publication
(10) Pub. No.: US 2009/0075429 A1
(43) Pub. Date: Mar. 19, 2009

(54) Sheet-Like Underfill Material and Semiconductor Device Manufacturing Method

(75) Inventors: Akinori Sato, Saitama (JP); Osamu Yamazaki, Saitama (JP); Kazuhiro Takahashi, Saitama (JP)

Correspondence Address: THE WEBB LAW FIRM, P.C., 700 KOPPERS BUILDING, 436 SEVENTH AVENUE, PITTSBURGH, PA, 15219, US

(73) Assignee: LINTEC CORPORATION, Tokyo (JP)

(21) Appl. No.: 11/912,825

(22) PCT Filed: Apr. 19, 2006
(86) PCT No.: PCT/JP2006/308190

§ 371 Date: Oct. 26, 2007

(30) Foreign Application Priority Data
Apr. 27, 2005 (JP) 2005-129502

(51) Int. Cl. H01L 21/50; B32B 7/12

(52) U.S. Cl. 438/118; 428/352; 257/E21.499

(57) ABSTRACT

A sheet-like underfill material includes a base and adhesive layer provided peelably on the base for use in a flip chip mounting process in the manufacture of a semiconductor device. The process includes laminating a sheet-like underfill material onto a circuit face of a semiconductor wafer having bumps on its circuit face and, simultaneously, allowing the bumps to pierce the adhesive layer and allowing the tops of the bumps to penetrate the base. The base has a storage elastic modulus of 1.0×10⁶ Pa to 4.0×10⁹ Pa, a breaking stress of 1.0×10⁵ Pa to 2.0×10⁸ Pa, and a Young's modulus of 1.0×10⁷ Pa to 1.1×10¹⁰ Pa. The adhesive layer has a storage elastic modulus of 1.0×10⁴ Pa to 1.0×10⁷ Pa and a breaking stress of 1.0×10³ Pa to 3.0×10⁷ Pa.

### TECHNICAL FIELD

The present invention relates to a sheet-like underfill material for use in flip chip mounting and a process for producing a semiconductor device using the same.

### BACKGROUND ART

For mounting multipin LSI packages to prepare MPUs, gate arrays or the like onto printed wiring boards, a flip chip mounting method has hitherto been adopted in which convex electrodes (bumps) made of eutectic solder, high-temperature solder, gold or the like are formed on a connection pad part of a semiconductor chip and are confronted with and are brought into contact with corresponding terminal parts on a chip mounting substrate by the so-called “facedown method” for melt/diffusion bonding. In this method, however, there is a fear that, upon exposure to a periodical temperature fluctuation, the joint is broken due to a difference in coefficient of thermal expansion between the semiconductor chip and the chip mounting substrate. To overcome this problem, a method has been proposed in which a heat curable liquid resin (an underfill material) is injected into a gap between the whole surface area of the semiconductor chip connected in the state of facedown, on where the bump electrodes are provided and a printed wiring board which faces the bump electrodes, and is then cured to bond the whole face of the bump joint portion to the chip mounting substrate, whereby thermal stress focused on the bump electrodes is dispersed to prevent breaking. The gap between the semiconductor chip and the chip mounting substrate in the flip chip mounting, however, is as small as 40 to 200 μm. This causes problems including that a considerable time is required for the step of filling the underfill material without forming any void, and viscosity control between lots of the underfill material is complicated.

In order to overcome these problems, for example, Japanese Patent Laid-Open No. H09-213741, H10-242208, and H10-270497 propose a technique in which a sheet-like heat curable resin or a thermoplastic resin is sandwiched between a semiconductor chip and a chip mounting substrate followed by thermocompression bonding. However, it should be noted that the technique proposed in Japanese Patent Laid-Open No. H09-213741 requires the additional step of providing a seal part so as to surround the bump part with a seal material and thus causes a problem that the process becomes complicated and, at the same time, the formation of voids cannot be fully avoided. In the proposal in Japanese Patent Laid-Open No. H10-242208, the positioning of the underfill resin is necessary, and, there is a possibility that the amount of the underfill resin is non-uniform (excessive or insufficient) in some places, and, further, escape hole-derived voids are formed. In Japanese Patent Laid-Open No. H10-270497, bump electrodes of a semiconductor chip penetrate into an insulating adhesive film and are connected to terminal parts of a chip mounting substrate. This causes such problem, in view process and reliability, that the insulating adhesive film cover sometimes remains on the top of the bump electrodes, to thereby leading insufficient connection reliability. Further, in recent years, due to an increasing demand for a thickness reduction in semiconductor packages, it is common practice to grind a semiconductor chip to a small thickness. To this end, in the prior art technique, processing has been carried out through a complicated process which comprises pressure-bonding a backgrind tape to the bump electrode face of a wafer having circuits formed thereon, grinding the backside of the wafer, peeling the tape, cutting the wafer into individual chips by dicing, and conducting bonding. A further problem arises that damage to wafers occurs during transfer or handling of the ground thin wafers.

In order to solve these problems, Patent document 1 proposes a sheet for semiconductor chip mounting, comprising a heat curing resin layer having substantially the same thickness as the bump height of the semiconductor chip to be mounted, provided on one side of a synthetic resin film. The lamination of this sheet for semiconductor chip mounting onto the wafer is carried out by thermocompression bonding at a temperature between the softening temperature of the heat curing resin layer before curing and the curing temperature of the heat curing resin.

### Patent Document 1; JP-A No. 2002-118147

### DISCLOSURE OF THE INVENTION

### Object of the Invention

In the sheet for semiconductor chip mounting proposed in the Patent document 1, bumps are buried into the resin layer only with flowing the heat curing resin layer to make conductivity. Accordingly, the operation may become difficult since the temperature and the pressure greatly affect the fluidity of the resin layer. For example, when the temperature is elevated for fluidity increase purposes, the heat curing resin is undesirably cured. On the other hand, increasing the pressure results in undesirably increased load at a local area of the wafer where the bumps are formed.

In recent years, stud bumps with a sharp tip are adopted as a kind of the above bumps. Even the stud bumps are used in the process disclosed in the Patent document 1, the problems as described above are still remained, and the temperature and the pressure should be controlled precisely. Further, in the stud bumps, the height of the bump is larger than the diameter of the bump, and, thus, the stud bumps are disadvantageous in that the tops of the bumps are likely to be broken, and, further, air is likely to be caught up in roots of the bumps, leading to a fear of void formation.

An object of the present invention is to provide a sheet-like underfill material, which can eliminate the need to precisely control the temperature or pressure, and to provide a semiconductor device utilizing the sheet-like underfill material. In particular, an object of the present invention is to provide a sheet-like underfill material, which can form a void-free underfill even when the shape of the bump is like a stud bump, and to provide semiconductor device utilizing the sheet-like underfill.

### Means to Attain the Object

The substances of the present invention which attain the above object are as follows:

(1) A sheet-like underfill material for use in a flip chip mounting process of a semiconductor, said sheet-like underfill material comprising:

a base material; and an adhesive layer provided peelably on the base material,

said base material having a storage elastic modulus of 1.0×10⁶ Pa to 4.0×10⁹ Pa, a breaking stress of 1.0×10⁵ Pa to 2.0×10⁸ Pa, and a Young's modulus of 1.0×10⁷ Pa to 1.1×10¹⁰ Pa,

said adhesive layer having a storage elastic modulus of 1.0×10⁴ Pa to 1.0×10⁷ Pa and a breaking stress of 1.0×10³ Pa to 3.0×10⁷ Pa.

(2) The sheet-like underfill material according to the above item (1), characterized in that

said adhesive layer is formed of a hardenable pressure-sensitive adhesive which is able to be laminated at normal temperatures,

the storage elastic modulus, breaking stress, and Young's modulus of said base material and the storage elastic modulus and breaking stress of said adhesive layer are values as measured at normal temperatures (25° C.).

(3) The sheet-like underfill material according to the above item (1), characterized in that

said adhesive layer is formed of a thermoplastic adhesive which can be laminated at an lamination temperature of 100° C. or below, and

the storage elastic modulus, breaking stress, and Young's modulus of said base material and the storage elastic modulus and breaking stress of said adhesive layer are values as measured at the lamination temperature.

(4) A process for producing a semiconductor device, comprising the steps of:

laminating a sheet-like underfill material according to any one of the above items (1) to (3) onto a circuit face of a semiconductor wafer having bumps on its circuit face so that said bumps pierce said adhesive layer;

cutting the semiconductor wafer to divide each circuit into individual chips;

peeling said base material from the surface of said adhesive layer to expose the tops of the bumps; and

mounting the bumps-formed-face of said chip on predetermined position of a chip mounting substrate and bonding and fixing the chip onto the chip mounting substrate via the adhesive layer while ensuring conductivity between the chip and the chip mounting substrate.

(5) The process for producing a semiconductor device according to the above item (4), characterized in that, at such a state that the tops of the bumps are exposed, the tops of the bumps protrude by 2 μm or more from the adhesive layer face.

(6) The process for producing a semiconductor device according to the above item (4) or (5), characterized in that the bumps are stud bumps.

### EFFECT OF THE INVENTION

According to the sheet-like underfill material of the present invention which is applicable to flip chip mounting and the semiconductor device utilizing the same, the underfill can be simply formed on a semiconductor wafer having bumps without precisely controlling the temperature and pressure. Further, even when the bumps are stud bumps, voids are not formed around the roots of the bumps and the like.

### BRIEF DESCRIPTION OF THE DRAWINGS

FIG. 1 is a cross-sectional view of a sheet-like underfill material according to the present invention;

FIG. 2 is a cross-sectional view of a semiconductor wafer with bumps formed thereon;

FIG. 3 is illustrating such a state that a sheet-like underfill material is laminated to a wafer; and

FIG. 4 is illustrating such a state that bumps are extended through an adhesive layer.

### ILLUSTRATION OF THE SYMBOLS

1: base material,
2: adhesive layer,
3: release film,
4: sheet-like underfill material,
5: bump,
6: semiconductor wafer, and
7: semiconductor chip.

### BEST MODE FOR CARRYING OUT THE INVENTION

The present invention will be described in more detail with reference to the accompanying drawings.

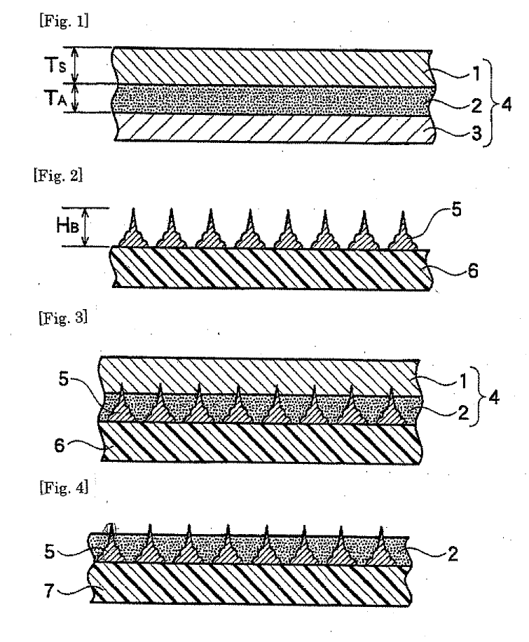

As shown in FIG. 1, the sheet-like underfill material for use in flip chip mounting according to the present invention (hereinafter referred to simply as “sheet-like underfill material 4”) comprises a base material 1 and an adhesive layer 2 provided on one side of the base material. Prior to use, a release film 3 for protecting the adhesive layer 2 is temporarily provided on the adhesive layer 2.

The sheet-like underfill material 4 according to the present invention can be applied to an adherend such as a semiconductor wafer without the need to conduct precise control of the temperature and pressure. In particular, the sheet-like underfill material 4 according to the present invention is characterized in that the base material 1 has the following properties.

The storage elastic modulus of the base material 1 is 1.0×10⁶ Pa to 4.0×10⁹ Pa, preferably 1.0×10⁷ Pa to 1.0×10⁹ Pa, more preferably 5.0×10⁷ Pa to 5.0×10⁸ Pa. The breaking stress of the base material 1 is 1.0×10⁵ Pa to 2.0×10⁸ Pa, preferably 1.0×10⁶ Pa to 1.0×10⁸ Pa, more preferably 5.0×10⁶ Pa to 5.0×10⁷ Pa. The Young's modulus of the base material 1 is 1.0×10⁷ Pa to 1.1×10¹⁰ Pa, preferably 2.0×10⁷ Pa to 1.0×10⁹ Pa, more preferably 5.0×10⁷ Pa to 5.0×10⁸ Pa. The storage elastic modulus, breaking strength and Young's modulus of the base material 1 are values as measured at a temperature for laminating the sheet-like underfill material to an adherend. That is, when the sheet-like underfill material is laminated at normal temperatures, the values of the above various properties are those as measured at normal temperatures (25° C.). On the other hand, when the lamination temperature is 70° C., the values of the above various properties are those as measured at 70° C.

In the case of an excessively high storage elastic modulus of the base material 1, when the sheet-like underfill material 4 is mounted to the bump face followed by pressing the assembly, the adhesive layer 2 is hardly deformed and, consequently, the top of the bump 5 cannot break through the adhesive layer 2. On the other hand, when the storage elastic modulus is excessively low, the pressure to the sheet-like underfill material 4 is excessively dispersed in the adhesive layer 2 and, consequently, the roots of the bumps 5 cannot be satisfactorily filled with the adhesive.

The tops of the bumps 5 piercing the adhesive layer 2 tears the base material 1 partially and is penetrated into the lower face of the base material 1. When the breaking stress of the base material 1 is too high, the bumps 5 cannot tear the base material 1 and cannot pierce the adhesive layer, or the tops of the protruded bumps 5 cannot go straight ahead and are bent, leading to a fear of causing loose connection with the chip mounting substrate. When the breaking stress of the base material 1 is too low, mechanical handleability is poor such that, for example, the sheet material is likely to tear at the time of lamination or peeling.

When the Young's modulus of the base material 1 is too high, the tops of the bumps 5 piercing the adhesive layer 2 is collapsed, leading to a fear of causing loose connection. On the other hand, when the Young's modulus of the base material 1 is too low, void formation may occur by tension at lamination of the sheet-like underfill material 4 to the bump face, that cause disadvantageous elongation of the adhesive layer 2 and the like to thereby generate elliptical voids not filled with the adhesive behind the bump 5 against the laminating direction of the sheet-like underfill material 4.

The base material 1 is not particularly limited so far as the above properties are satisfied, and examples thereof include films such as polyethylene films, polypropylene films, polybutene films, polybutadiene films, polymethylpentene films, polyvinyl chloride films, vinyl chloride copolymer films, polyurethane films, ethylene-vinyl acetate films, ionomer resin films, ethylene (meth)acrylic acid copolymer films, ethylene-(meth)acrylic ester copolymer films, and fluororesin films. Crosslinked films of these materials may also be used. Further, laminated films of these materials are also possible. These films may be any of transparent films, colored films, or opaque films.

In the production process of a semiconductor device according to the present invention, as described later, the adhesive layer 2 on the base material 1 is transferred onto the circuit face of a chip (a wafer). Accordingly, the base material 1 and the adhesive layer 2 are stacked peelably from each other, and, preferably, the surface tension of the base material 1 on its surface in contact with the adhesive layer 2 is not more than 40 mN/m, more preferably not more than 37 mN/m, particularly preferably not more than 35 mN/m. The film having such low surface tension can be obtained by properly selecting the material. Alternatively, the film can also be obtained by subjecting a film to release treatment, that is, by coating a release agent such as a silicone resin or an alkyd resin onto the surface of a film.

The film thickness of the base material 1 is generally 10 to 500 μm, preferably 15 to 300 μm, particularly preferably about 20 to 250 μm.

The adhesive layer 2 used in the present invention has a storage elastic modulus of 1.0×10⁴ Pa to 1.0×10⁷ Pa, preferably 2.0×10⁴ Pa to 5.0×10⁶ Pa, more preferably 5.0×10⁴ Pa to 1.0×10⁶ Pa and has a breaking stress of 1.0×10³ Pa to 3.0×10⁷ Pa, preferably 1.0×10⁴ Pa to 2.0×10⁷ Pa, more preferably 1.0×10⁵ Pa to 8.0×10⁶ Pa. The storage elastic modulus and breaking strength are also values as measured at a temperature for the application of the sheet-like underfill material to an adherend.

When the storage elastic modulus of the adhesive layer 2 is too high, the adhesive layer 2 is less likely to be deformed and, consequently, the bumps 5 will not penetrate the adhesive layer 2 to the extent that roots of the bumps 5 come in contact with the adhesive layer 2. When the storage elastic modulus is too low, the adhesive is attached to the bumps 5 in the course of piercing of the bumps 5 through the adhesive layer 2 and the tops of the bumps are disadvantageously covered with the adhesive, leading to a fear of causing loose connection.

When the breaking stress of the adhesive layer 2 is too high, the bumps 5 undergo high resistance due to the transfer of the adhesive layer 2 and, consequently, the bumps 5 are hardly pierce the adhesive layer 2. When the breaking stress of the adhesive layer 2 is too low, the adhesive layer 2 is cracked at application of the sheet-like underfill material to the bump face and becomes unusable.

Conventional adhesives may be used as the above adhesive without particular limitation so far as they have the above properties. The adhesive may be heat curable or thermoplastic. The heat curable adhesive may be a hardenable pressure-sensitive adhesive (here-in-after “HPSA”) which is tacky at normal temperatures. When the adhesive is hardenable by heating, the above-described storage elastic modulus and breaking stress of the adhesive layer are values as measured before heat curing.

The HPSA usable for adhesive layer 2 is an adhesive that exhibits tackiness at normal temperatures in the initial state and is hardened by triggering upon heating to exhibit strong adhesion. The pressure-sensitive adhesive having the above storage elastic modulus and breaking strength permits the bumps to pierce the adhesive layer 2 at normal temperatures and can be applied to an adherend at normal temperatures. Therefore, the temperature control is unnecessary, and the pressure control is also very easy.

For example, a mixture of a binder resin, which has pressure-sensitivity of adhesion at normal temperatures, with a thermo-setting resin may be mentioned as the HPSA which has pressure-sensitivity of adhesion at normal temperatures. Binder resins which have pressure-sensitivity of adhesion at normal temperatures include, for example, acrylic resins, polyester resins, polyvinyl ethers, urethane resins, and polyamides. Thermo-setting resins which are generally used in the present invention include epoxy resins, phenoxy resins, phenol resins, resorcinol resins, urea resins, melamine resins, furan resins, unsaturated polyester resins, and silicone resins. They are used in combination with a suitable curing accelerator. Various such thermo-setting resins are known, and, in the present invention, various conventional thermo-setting resins are usable without particular limitation. The incorporation of energy ray-curable resins such as urethane acrylate oligomers in the HPSA is preferred from the viewpoint of regulating the peelability from the base material 1. The incorporation of the energy ray-curable resin in the HPSA is advantageous in that, before energy ray irradiation, adhesive layer has good adhesion to the base material 1, while, after energy ray irradiation, the adhesive layer 2 can be easily separated from the base material 1. In this case, at the time of the application of the adherend, since energy ray irradiation is not carried out, the storage elastic modulus and breaking strength of the adhesive layer 2 are values as measured before the adhesive layer 2 is cured by energy ray irradiation. Energy rays usable for irradiation include ultraviolet light and electron beams.

The HPSA comprising the above components has both energy ray-curability and hardenablity by heating, can fix the wafer closely to the base material 1, and, in mounting, can be used as an adhesive for bonding a chip to a chip mounting substrate. The HPSA is then subjected to hardening by heating to thereby finally provide a highly impact resistant hardened product. Further, it has good balance between the shear strength and the peel strength and can maintain satisfactory adhesive properties even under severe high temperature and humidity conditions.

The adhesive layer 2 may be formed of a thermoplastic adhesive. The thermoplastic adhesive has non-pressure-sensitivity of adhesion at normal temperatures and can be bonded to an adherend upon exposure to heat under pressure. The thermoplastic adhesive usable in the present invention changes into having the above-described storage elastic modulus and breaking strength at an applicable temperature and the lamination temperature is preferably 100° C. or below. Such thermoplastic adhesives include adhesive films composed mainly of various thermoplastic resins such as polyimide resins, polyester resins, acrylic resins, polyvinyl acetates, polyvinyl butyrals, and polyamide resins. Among them, polyimide resin adhesives are particularly preferred because they have high heat resistance. Specifically, for example, UL 27 (trade name) commercially available from Ube Industries, Ltd. may be used. The polyimide resin adhesives may be prepared from thermoplastic polyamide-imide resins.

The thickness of the adhesive layer 2 is approximately generally 10 to 500 μm, preferably 15 to 300 μm, particularly preferably 20 to 250 μm.

In this case, in order that the adhesive layer covers the circuit face without void formation and can be pierced by the bumps, the ratio of the average height of the bumps (H_{B}) to the thickness of the adhesive layer (T_{A}) (i.e., H_{B}/T_{A}) is in the range of 1.0/0.3 to 1.0/0.95, preferably 1.0/0.5 to 1.0/0.9, more preferably 1.0/0.6 to 1.0/0.85, particularly preferably 1.0/0.7 to 1.0/0.8. As shown in FIG. 2, the average height of the bumps (H_{B}) is the height from the chip surface (circuit face except for bumps) to the top of the bumps. When a plurality of bumps are present, the average height is an arithmetic mean of the height of these bumps.

When the bump height is excessively large relative to the thickness of the adhesive layer, the chip surface (circuit face except for bumps) and the chip mounting substrate do not contact completely to thereby form a space therebetween, which causes void formation. On the other hand, when the adhesive layer is excessively thick, the bumps cannot pierce the adhesive layer to thereby cause loose conductivity.

In the sheet-like underfill material 4, the ratio of the thickness of the base material (T_{S}) to the thickness of the adhesive layer (T_{A}) (i.e., T_{S}/T_{A}) is preferably 0.5 or more, more preferably 1.0 or more, particularly preferably 2.0 or more.

When the thickness of the base material is excessively thin relative to the thickness of the adhesive layer, in some cases, bumps cannot pierce the adhesive layer, leading to a fear of causing loose conductivity. The reason for this is believed to reside in that, when the base material has a certain level of thickness, the base material functions as a cushion, which permits the tops of the bumps pierce the adhesive layer to penetrate in the base material, and, consequently, the bumps can easily pierce the adhesive layer, whereas, when the base material is excessively thin, cushioning function of the base material cannot be expected.

The sheet-like underfill material 4 is preferably used in a production process of a semiconductor device including the step of, simultaneously with the lamination of the sheet-like underfill material to the circuit face of a semiconductor wafer having bumps on its circuit face, allowing the bumps to pierce the adhesive layer and the tops of the bumps to penetrate in the base material, particularly in the production process of a semiconductor device according to the present invention which will be described later.

The volume resistivity of the adhesive layer 2 in the sheet-like underfill material 4 according to the present invention is preferably 10¹⁰ Ω·cm or more, particularly preferably 10¹² Ω·cm or more. When the adhesive layer 2 has the above volume resistivity, each part between bumps in the flip chip bonded device can be reliably rendered insulative and, thus, leak occurrence can be prevented.

As described above, in order to protect the adhesive layer 2 before the use of the sheet-like underfill material 4 according to the present invention, a release film 3 may be temporarily provided on the adhesive layer 2. Various release films which have hitherto been used in pressure-sensitive adhesive tapes can be used without particular limitation.

Next, a production process of a semiconductor device utilizing the sheet-like underfill material 4 according to the present invention will be described.

At the outset, as shown in FIG. 2, a semiconductor wafer 6 having bumps 5 on its circuit face is provided. The circuit and bumps may be formed by any conventional methods. The shape of the bumps is not particularly limited. For example, the sheet-like underfill material according to the present invention is suitable for use in bumps having a sharp front end top, such as stud bumps.

Next, the adhesive layer 2 of the sheet-like underfill material 4 according to the present invention is laminated to the circuit face of the semiconductor wafer 6. The sheet-like underfill material 4 may be supplied in a long tape form. Alternatively, the sheet-like underfill material 4 may be supplied in such a state that the sheet-like underfill material 4 which has been punched into a wafer shape is continuously laminated onto the release film 3. When the sheet-like underfill material 4 is supplied in a long tape form, after the completion of the laminating of the sheet-like underfill material 4, the sheet-like underfill material 4 is cut along the outer periphery of the semiconductor wafer 6.

The sheet-like underfill material 4 is laminated to the circuit face (bump face) while pressing with a metallic or rubber laminator roller. The applicator may have such a structure that a heating mechanism such as a heater is provided in the laminator roller and/or a table for supporting the wafer so that heat can be applied in pressing the sheet-like underfill material 4 and the semiconductor wafer 6. When the adhesive layer 2 is formed of a HPSA, since the HPSA has pressure-sensitivity of adhesion at normal temperatures, there is no need to heat the adhesive layer 2 in the application of the sheet-like underfill material 4.

In the step of laminating the sheet-like underfill material 4, the sheet-like underfill material 4 and the semiconductor wafer 6 may be strongly pressed so that the bumps 5 can easily pierce the adhesive layer 2. Pressing may be carried out while applying a certain level of tension to the sheet-like underfill material 4. Upon the application of the sheet-like underfill material 4 in this way, the bumps 5 pierce the adhesive layer 2 and, further, the tops of the bumps penetrate in the base material 1.

As a result, as shown in FIG. 3, the circuit face and bumps of the semiconductor wafer 6 are brought to such a state as protected with the sheet-like underfill material 4. In this state, the semiconductor wafer 6 may be subjected to backside grinding and other backside processing.

Next, the semiconductor wafer 6 is cut by each circuit so as to be divided into individual chips. The wafer 6 can be cut and divided by any method without particular limitation, and conventional various methods may be used. For example, a method may be adopted in which a conventional dicing tape is applied to the backside of the wafer 6, the assembly is fixed by means of a ring frame adhered to the dicing tape, and the wafer is cut and separated by a dicing device to prepare chips. Alternatively, various dicing methods such as laser dicing may be adopted.

A method may also be adopted in which, after the formation of grooves having a predetermined depth from the circuit face side of the wafer prior to the lamination of the sheet-like underfill material 4 to the wafer circuit face, the sheet-like underfill material 4 is applied onto the circuit face, and the assembly is ground from the backside of the wafer to remove the bottom part of the grooves to prepare chips from the wafer. This method is known also as “pre-dicing method” and is effective means for preparing ultrathin chips. A further method may also be adopted in which brittle parts as starting points for cutting are formed in the semiconductor wafer and thermal or mechanical impact is applied to the wafer to cause breaking from the starting point and thus to prepare chips from the wafer. The starting point for cutting may be formed, for example, by collecting a laser beam in the wafer to partially form modified parts in the wafer or form grooves.

Next, the base material 1 is peeled from the surface of the adhesive layer 2 to expose the tops of the bumps. The base material 1 may be peeled before or after the above chip preparation step. When the adhesive layer 2 is energy ray-curable, preferably, prior to the peeling of the base material 1, the adhesive layer is irradiated with energy ray to lower the adhesive strength followed by the peeling of the base material 1.

The completion of the above steps can provide a chip 7 as shown in FIG. 4 in which the circuit face is covered with an adhesive layer, and the tops of the bumps pierce the adhesive layer and protrude from the adhesive layer 2. In the present invention, at such a stage that the bump top is exposed, the bump top preferably protrude from the adhesive layer surface by 2 μm or more, more preferably 4 μm or more, particularly preferably 6 to 20 μm. The height from the adhesive layer surface to the bump top will be hereinafter referred to as “bump penetration amount.” The bump penetration amount can be regulated to a suitable range by properly selecting the ratio of the bump height (H_{B}) to the adhesive layer thickness (T_{A}) (i.e., H_{B}/T_{A}) and sheet-like underfill material application conditions. In general, the larger the value of H_{B}/T_{A}, the larger the bump penetration amount. Further, the higher the sheet-like underfill material laminating pressure, the larger the bump penetration amount.

Next, positioning is carried out so that the bumps of the chip 7 face electrodes of a chip mounting substrate, and the chip is mounted on the chip mounting substrate so as to ensure electrical continuity between the chip and the chip mounting substrate. Thereafter, the adhesive layer 2 is heat cured to strongly bond the chip to the chip mounting substrate.

Thereafter, a semiconductor device is prepared through conventional steps such as resin sealing.

### INDUSTRIAL APPLICABILITY

According to the sheet-like underfill material of the present invention, an underfill can be simply formed on a semiconductor wafer having bumps without particular regulation of the temperature and pressure. Further, even in the case that the bumps have a unique shape such as stud bumps, voids are not formed. Therefore, the process is simplified, and the production cost of semiconductor devices can be reduced.

### EXAMPLES

The present invention will be described in more detail with reference to the following examples. However, it should be noted that the present invention is not limited to these examples only.

In the following examples and comparative examples, “bump penetration amount” was evaluated as follows.

### “Bump Penetration Amount”

Gold ball solders were formed at predetermined positions on a wafer with a bump bonder (SBB4, manufactured by SHINKAWA LTD.) and were melted and extended to form bumps having a height of 65 μm.

In sheet-like underfill materials laminated to a chip having bumps in Examples 1 to 10 and Comparative Examples 1 and 2, whether or not all the bump tops protruded from the adhesive layer surface side was inspected by observation of the chip after pickup with using an electron microscope (Hitachi Scanning Electron Microscope S-2360, manufactured by Hitachi, Ltd.). Subsequently, the height of the bumps which protruded from the adhesive layer surface side (unit: μm, distance from the adhesive layer surface to bump tops) was measured (n=10) with an ultra wide view confocal microscope (HD100D, manufactured by Lasertec Corp.), and the average value of the data was determined as the bump penetration amount.

The storage elastic modulus, breaking stress and Young's modulus of the base material were measured as follows.

### “Storage Elastic Modulus of Base Material”

The base material was cut into a size of 4 mm×30 mm (length between grips: about 20 mm) to prepare a sample for dynamic viscoelasticity measurement. The storage elastic modulus was measured with a dynamic viscoelasticity measuring device (RHEOVIBRON DDV-II-EP, manufactured by Orientec Co. Ltd.) at a frequency of 11 Hz.

### “Breaking Stress of Base Material” and “Young's Modulus of Base Material”

The breaking stress and Young's modulus of base materials used in sheet materials in the examples and comparative examples were measured according to JIS K 7127.

The storage elastic modulus and breaking stress of the adhesive layer before hardening were measured as follows.

### “Storage Elastic Modulus of Adhesive Layer”

The adhesive layer was stacked to a thickness of 3 mm to prepare a sample for dynamic viscoelasticity measurement. The storage elastic modulus was measured at a frequency of 1 Hz with a dynamic viscoelasticity measuring device (RDA-II, manufactured by Rheometrix Corp.).

### “Breaking Stress of Adhesive Layer”

The adhesive layer was stacked to a thickness of 200 μm and was cut into a size of 15 mm×50 mm to prepare a sample for a tensile test (length between grips: 30 mm). The sample was pulled with a tensile tester (Tensilon RTA-100, manufactured by Orientec Co. Ltd.) at a tensile speed of 200 mm/min until the sample was broken to determine the breaking stress.

Further, in the examples and comparative examples, the following binder resins [acrylic copolymers (A1 to A3) and butyral resin (A4)], a thermo-setting resin (B), heat-activatable latent curing agent (C), energy ray-polymerizable compound (D), photopolymerization initiator (E) and crosslinking agent (F) as for the ingredients of the HPSA, and polyimide resins (G1, G2) as for the ingredients of the thermoplastic adhesive were used.

### (A) Binder Resins

A1: A solution prepared by dissolving a copolymer having a weight average molecular weight of 300000, prepared by copolymerizing 55 parts by weight of butyl acrylate, 10 parts by weight of methyl methacrylate, 20 parts by weight of glycidyl methacrylate and 15 parts by weight of 2-hydroxyethyl acrylate, in an organic solvent (toluene/ethyl acetate=6/4) (solid content 50%)

A2: A solution prepared by dissolving a copolymer having a weight average molecular weight of 800000, prepared by copolymerizing 55 parts by weight of butyl acrylate, 10 parts by weight of methyl methacrylate, 20 parts by weight of glycidyl methacrylate and 15 parts by weight of 2-hydroxyethyl acrylate, in an organic solvent (toluene/ethyl acetate=6/4) (solid content 35%)

A3: A solution prepared by dissolving a copolymer having a weight average molecular weight of 780000, prepared by copolymerizing 30 parts by weight of butyl acrylate, 10 parts by weight of methyl methacrylate, 10 parts by weight of glycidyl methacrylate and 15 parts by weight of 2-hydroxyethyl acrylate and 35 parts by weight of vinyl acetate, in an organic solvent (toluene/ethyl acetate=6/4) (solid content 35%).

A4: A solution prepared by dissolving butyral resin (DENKA BUTYRAL #6000-C, manufactured by Denki Kagaku Kogyo K.K.) in an organic solvent (methyl ethyl ketone/toluene/ethyl acetate=2/1/1) (solid content 30%)

### (B) A Thermo-Setting Resin (Epoxy Resin)

A mixture composed of 22 parts by weight of a bisphenol A type epoxy resin (Epikote 828, epoxy equivalent 180 to 200 eq/g, manufactured by Japan Epoxy Resins Co., Ltd.), a solution (solid content 60%) prepared by dissolving a solid bisphenol A type epoxy resin (Epikote 1055, epoxy equivalent 800 to 900 eq/g, manufactured by Japan Epoxy Resins Co., Ltd.) in an organic solvent (methyl ethyl ketone) in an amount corresponding to 44 parts by weight in terms of solid content, and a solution (solid content 70%) prepared by dissolving an o-cresol novolak type epoxy resin (EOCN-104S, epoxy equivalent 210 to 230 g/eq, manufactured by Nippon Kayaku Co., Ltd.) in an organic solvent (methyl ethyl ketone) in an amount corresponding to 14 parts by weight in terms of solid content.

### (C) Heat-Activatable Latent Curing Agent

A solution (solid content 30%) prepared by dissolving a mixture of 1 part by weight of dicyandiamide (Hardener 3636 AS, manufactured by Asahi Denka Kogyo Ltd.) with 1 part by weight of 2-phenyl-4,5-hydroxymethylimidazole (CURESOL 2PHZ, manufactured by SHIKOKU CHEMICALS CORPORATION) in an organic solvent (methyl ethyl ketone)

### (D) Energy Ray-Curable Resin

Dipentaerythritol hexaacrylate

### (E) Photopolymerization Initiator

A solution (solid content 30%) prepared by dissolving IRGACURE 184 (manufactured by Ciba Specialty Chemicals, K.K.) in an organic solvent (toluene).

### (F) Isocyanate Crosslinking Agent

A solution (solid content 38%) prepared by dissolving Coronate L (manufactured by Nippon Polyurethane Industry Co., Ltd.) in an organic solvent (toluene).

### (G) Thermoplastic Resins (Polyimide Resin)

G1: UL 27 (trade name, manufactured by Ube Industries, Ltd.)

G2: UL 004 (trade name, manufactured by Ube Industries, Ltd.)

### Example 1

20 parts by weight of (A1), 80 parts by weight of (B), 2 parts by weight of (C), 10 parts by weight of (D), 0.3 part by weight of (E), and 0.3 part by weight of (F) of above components were mixed (in terms of solid weight ratio) together, and methyl ethyl ketone was mixed therein so as to have a solid content of 55% to prepare a HPSA composition. The HPSA composition was coated onto release treated face of a release film (SP-PET 3811, thickness 38 μm, manufactured by Lintec Corporation) so as to have a coating thickness of 50 μm on a dry basis, and the coating was dried at 100° C. for one min. Next, the assembly was laminated onto a low-density polyethylene film (thickness 110 μm, surface tension 34 mN/m) to prepare a sheet-like underfill material.

### Example 2

40 parts by weight of (A2), 80 parts by weight of (B), 2 parts by weight of (C), 10 parts by weight of (D), 0.3 part by weight of (E), and 0.3 part by weight of (F) of above components were mixed (in terms of solid weight ratio) together, and methyl ethyl ketone was mixed therein so as to have a solid content of 55% to prepare a HPSA composition. The HPSA composition was coated onto release treated face of a release film (SP-PET 3811) so as to have a coating thickness of 50 μm on a dry basis, and the coating was dried at 100° C. for one min. Next, the assembly was laminated onto a low-density polyethylene film (thickness 110 μm) to prepare a sheet-like underfill material.

### Example 3

20 parts by weight of (A2), 80 parts by weight of (B), 2 parts by weight of (C), 5 parts by weight of (D), 0.15 part by weight of (E), and 0.3 part by weight of (F) of above components were mixed (in terms of solid weight ratio) together, and methyl ethyl ketone was mixed therein so as to have a solid content of 55% to prepare a HPSA composition. The HPSA composition was coated onto release treated face of a release film (SP-PET 3811) so as to have a coating thickness of 50 μm on a dry basis, and the coating was dried at 100° C. for one min. Next, the assembly was laminated onto a low-density polyethylene film (thickness 110 μm) to prepare a sheet-like underfill material.

### Example 4

20 parts by weight of (A3), 80 parts by weight of (B), 2 parts by weight of (C), 10 parts by weight of (D), 0.3 part by weight of (E), and 0.3 part by weight of (F) of above components were mixed (in terms of solid weight ratio) together, and methyl ethyl ketone was mixed therein so as to have a solid content of 45% to prepare a HPSA composition. The HPSA composition was coated onto release treated face of a release film (SP-PET 3811) so as to have a coating thickness of 50 μm on a dry basis; and the coating was dried at 100° C. for one min. Next, the assembly was laminated onto a low-density polyethylene film (thickness 110 μm) to prepare a sheet-like underfill material.

### Example 5

15 parts by weight of (A2), 5 parts by weight of (A4), 80 parts by weight of (B), 2 parts by weight of (C), 10 parts by weight of (D), 0.3 part by weight of (E), and 0.3 part by weight of (F) of above components were mixed (in terms of solid weight ratio) together, and methyl ethyl ketone was mixed therein so as to have a solid content of 45% to prepare a HPSA composition. The HPSA composition was coated onto release treated face of a release film (SP-PET 3811) so as to have a coating thickness of 50 μm on a dry basis, and the coating was dried at 100° C. for one min. Next, the assembly was laminated onto a low-density polyethylene film (thickness 110 μm) to prepare a sheet-like underfill material.

### Example 6

The above component (G1) was coated onto release treated face of a release film (SP-PET 3811) so as to have a coating thickness of 50 μm on a dry basis, and the coating was dried at 130° C. for one min. Next, the assembly was laminated onto a low-density polyethylene film (thickness 110 μm) to prepare a sheet-like underfill material.

### Example 7

The HPSA composition prepared in Example 1 was coated onto release treated face of a release film (SP-PET 3811) so as to have a coating thickness of 50 μm on a dry basis, and the coating was dried at 100° C. for one min. Next, the assembly was laminated onto a linear low-density polyethylene film (thickness 100 μm, surface tension 34 mN/m) to prepare a sheet-like underfill material.

### Example 8

The HPSA composition prepared in Example 1 was coated onto release treated face of a release film (SP-PET 3811) so as to have a coating thickness of 50 μm on a dry basis, and the coating was dried at 100° C. for one min. Next, the assembly was laminated onto an ethylene/methacrylic acid copolymer film (thickness 80 μm, ethylene/methacrylic acid=91/9 (weight ratio, surface tension 35 mN/m) to prepare a sheet-like underfill material.

### Example 9

The HPSA composition prepared in Example 1 was coated onto release treated face of a release film (SP-PET 3811) so as to have a coating thickness of 50 μm on a dry basis, and the coating was dried at 100° C. for one min. Next, the assembly was applied onto a vinyl chloride film (thickness 90 μm, surface tension 40 mN/m) to prepare a sheet-like underfill material.

### Example 10

The HPSA composition prepared in Example 1 was coated onto release treated face of a release film (SP-PET 3811) so as to have a coating thickness of 50 μm on a dry basis, and the coating was dried at 100° C. for one min. Next, the assembly was laminated onto a release treated polypropylene film (thickness 80 μm, surface tension 35 mN/m) to prepare a sheet-like underfill material.

### Comparative Example 1

The above component (G2) was coated onto release treated face of a release treated polyethylene naphthalate film (thickness 38 μm) so as to have a coating thickness of 50 μm on a dry basis, and the coating was dried at 130° C. for one min. Next, the assembly was laminated onto a low-density polyethylene film (thickness 110 μm, surface tension 35 mN/m) to prepare a sheet-like underfill material.

### Comparative Example 2

The HPSA composition prepared in Example 1 was coated onto release treated face of a release film (SP-PET 3811) so as to have a coating thickness of 50 μm on a dry basis, and the coating was dried at 100° C. for one min. Next, the assembly was laminated onto a polyethylene terephthalate film (thickness 50 μm, surface tension 38 mN/m) treated with release agent comprising alkyd resin to prepare a sheet-like underfill material.

The composition of each adhesive layer is shown in Table 1, and the results are summarized in Table 2.

### (Manufacturing Process of Semiconductor Devices)

Gold ball solders were formed at predetermined positions on a silicon wafer (6 inches, thickness 300 μm) using a bump bonder (SBB4, manufactured by SHINKAWA LTD.), were melted and extended, and were cut. Thus, a wafer having 65 μm-high stud bumps formed thereon was provided.

Sheet-like underfill materials of Examples 1 to 10 and Comparative Examples 1 and 2 were laminated to the bump face of a wafer by a rubber laminate roller (rubber hardness 50) with an laminator (RAD 3500 m/8, manufactured by Lintec Corporation) under conditions of laminating speed 3 mm/sec and load 3 MPa. The temperatures of laminate roller and the table were 25° C. except for Example 6 and Comparative Example 1. The temperatures of laminate roller and the table were 70° C. for Example 6 and were 100° C. for Comparative Example 1. Subsequently, except for Example 6 and Comparative Example 1, ultraviolet irradiation (quantity of light 110 mJ/cm², illuminance 150 mW/cm²) was carried out with using an ultraviolet light irradiation device (RAD 2000 m/8, manufactured by Lintec Corporation) to cure the adhesive layer.

Dicing tapes were applied to the base material side of the sheet-like underfill materials of Examples and Comparative Examples, and the wafers were cut and separated with a dicing device (DFG-2H/6T, manufactured by DISCO CORPORATION) to such a depth that the adhesive layer of the sheet-like underfill materials were completely cut, whereby chips were prepared. Next, in such a state that the adhesive layer remained on the bump face of the chip, the chip was pickuped from the base material layer of the sheet-like underfill material and was placed in a chip tray.

Next, the chip was mounted on a chip mounting substrate for evaluation having a wiring pattern corresponding to bump positions with using a flip chip bonder (FB30T-M, manufactured by Kyushu Matsushita Electric Co., Ltd.). For the flip chip bonder, the stage temperature was 60° C., the head temperature was 130° C., and the load was 20 N, and the time was 60 sec.

After mounting, except for Example 6 and Comparative Example 1, the assembly was held in an oven of 150° C. for 60 min to fully harden the HPSA layer and thus to prepare a semiconductor device. The resistance value across the terminals of the semiconductor device thus obtained was measured with a low resistivity meter (Loresta-GP MCP-T600, manufactured by Mitsubishi Chemical Corporation) for confirming electrical continuity between terminals to be conducted and insulation between other terminals in Examples 1 to 10. In Comparative Examples 1 and 2, no electrical continuity was confirmed between any terminals.

TABLE 1

| | Adhesive composition, parts by weight | | | | | | | |
|---|---|---|---|---|---|---|---|---|
| | Binder | | Component | Component | Component | Component | Component | Thermoplastic |
| | component | | B | C | D | E | F | resin |
| Examples 1 and 7 to | A1 (20) | | 30 | 2 | 10 | 0.3 | 0.3 | — |
| 10, and Comparative | | | | | | | | |
| Example 2 | | | | | | | | |
| Example 2 | A2 (40) | | 80 | 2 | 10 | 0.3 | 0.3 | — |
| 3 | A2 (20) | | 80 | 2 | 5 | 0.15 | 0.3 | — |
| 4 | A3 (20) | | 80 | 2 | 10 | 0.3 | 0.3 | — |
| 5 | A2 (15) | A4 (5) | 80 | 2 | 10 | 0.3 | 0.3 | — |

| | | | | | | | |
|---|---|---|---|---|---|---|---|
| 6 | — | — | — | — | — | — | G1 (100) |
| Comparative | — | — | — | — | — | — | G2 (100) |
| Example 1 | | | | | | | |

TABLE 2

| | Base material | | | | Adhesive layer | | | | |
|---|---|---|---|---|---|---|---|---|---|
| | | Storage | | | | Storage | | | |
| | Thick- | elastic | Breaking | Young's | Thick- | elastic | Breaking | Volume | Penetration |
| | ness, | modulus, | stress, | modulus, | ness, | modulus, | stress, | resistivity, | amount, |
| | μM | Pa | Pa | Pa | μm | Pa | Pa | Ω · cm | μm |
| Example 1 | 110 | 1.28 × 10⁸ | 1.19 × 10⁷ | 1.09 × 10⁸ | 50 | 1.40 × 10⁵ | 1.70 × 10⁵ | 1.24 × 10¹⁴ | 15.6 |
| 2 | 110 | 1.28 × 10⁸ | 1.19 × 10⁷ | 1.09 × 10⁸ | 50 | 1.98 × 10⁵ | 3.71 × 10⁶ | 3.46 × 10¹⁴ | 14.1 |
| 3 | 110 | 1.28 × 10⁸ | 1.19 × 10⁷ | 1.09 × 10⁸ | 50 | 3.40 × 10⁵ | 5.61 × 10⁶ | 2.23 × 10¹⁴ | 16.5 |
| 4 | 110 | 1.28 × 10⁸ | 1.19 × 10⁷ | 1.09 × 10⁸ | 50 | 2.45 × 10⁵ | 7.27 × 10⁶ | 1.56 × 10¹⁴ | 16.7 |
| 5 | 110 | 1.28 × 10⁸ | 1.19 × 10⁷ | 1.09 × 10⁸ | 50 | 5.10 × 10⁵ | 2.11 × 10⁷ | 5.12 × 10¹⁴ | 8.7 |
| 6 | 110 | 3.43 × 10⁷ | 6.33 × 10⁶ | 3.01 × 10⁷ | 50 | 3.01 × 10⁶ | 2.55 × 10⁷ | 3.15 × 10¹⁴ | 4.2 |
| 7 | 100 | 9.92 × 10⁷ | 2.89 × 10⁷ | 7.41 × 10⁷ | 50 | 1.40 × 10⁵ | 1.70 × 10⁵ | 1.24 × 10¹⁴ | 12.1 |
| 8 | 80 | 1.39 × 10⁸ | 2.52 × 10⁷ | 1.08 × 10⁸ | 50 | 1.40 × 10⁵ | 1.70 × 10⁵ | 1.24 × 10¹⁴ | 10.6 |
| 9 | 90 | 5.68 × 10⁸ | 2.59 × 10⁷ | 3.20 × 10⁸ | 50 | 1.40 × 10⁵ | 1.70 × 10⁵ | 1.24 × 10¹⁴ | 6.9 |
| 10 | 80 | 1.80 × 10⁹ | 9.76 × 10⁷ | 1.74 × 10⁹ | 50 | 1.40 × 10⁵ | 1.70 × 10⁵ | 1.24 × 10¹⁴ | 6.1 |
| Comparative | 110 | 4.77 × 10⁶ | 3.89 × 10⁶ | 1.47 × 10⁷ | 50 | 1.20 × 10⁷ | 3.31 × 10⁷ | 7.02 × 10¹⁴ | 0 |
| Example 1 | | | | | | | | | |
| 2 | 50 | 4.08 × 10⁹ | 2.09 × 10⁸ | 1.10 × 10¹⁰ | 50 | 1.40 × 10⁵ | 1.70 × 10⁵ | 1.24 × 10¹⁴ | 0 |

(Measuring temp. and Lamination temp.: Room temp. (25° C.) except for Example 6 and Comparative Example 1; 70° C. for Example 6, and 100° C. for Comparative Example 1)

1. A sheet-like underfill material for use in a flip chip mounting process of a semiconductor,
said sheet-like underfill material comprising: a base material; and an adhesive layer provided peelably on the base material,
said base material having a storage elastic modulus of 1.0×10⁶ Pa to 4.0×10⁹ Pa, a breaking stress of 1.0×10⁵ Pa to 2.0×10⁸ Pa, and a Young's modulus of 1.0×10⁷ Pa to 1.1×10¹⁰ Pa,
said adhesive layer having a storage elastic modulus of 1.0×10⁴ Pa to 1.0×10⁷ Pa and a breaking stress of 1.0×10³ Pa to 3.0×10⁷ Pa.

2. The sheet-like underfill material according to claim 1, wherein:
said adhesive layer is formed of a hardenable pressure-sensitive adhesive which is able to be laminated at normal temperatures,
the storage elastic modulus, breaking stress, and Young's modulus of said base material and the storage elastic modulus and breaking stress of said adhesive layer are values as measured at normal temperatures (25° C.).

3. The sheet-like underfill material according to claim 1, wherein:
said adhesive layer is formed of a thermoplastic adhesive which can be laminated at an lamination temperature of 100° C. or below, and
the storage elastic modulus, breaking stress, and Young's modulus of said base material and the storage elastic modulus and breaking stress of said adhesive layer are values as measured at the lamination temperature.

4. A process for producing a semiconductor device, comprising the steps of:
laminating a sheet-like underfill material according to claim 1 onto a circuit face of a semiconductor wafer having bumps on its circuit face so that tops of said bumps pierce said adhesive layer;
cutting the semiconductor wafer to divide each circuit into individual chips;
peeling said base material from the surface of said adhesive layer to expose the tops of the bumps; and
mounting the bumps-formed-face of said chip on predetermined position of a chip mounting substrate and bonding and fixing the chip onto the chip mounting substrate via the adhesive layer while ensuring conductivity between the chip and the chip mounting substrate.

5. The process for producing a semiconductor device according to claim 4, when the tops of the bumps are exposed, the tops of the bumps protrude by 2 μm or more from the adhesive layer face.

6. The process for producing a semiconductor device according to claim 4, wherein the bumps are stud bumps.

7. A process for producing a semiconductor device, comprising the steps of:
laminating a sheet-like underfill material according to claim 2 onto a circuit face of a semiconductor wafer having bumps on its circuit face so that tops of said bumps pierce said adhesive layer;
cutting the semiconductor wafer to divide each circuit into individual chips;
peeling said base material from the surface of said adhesive layer to expose the tops of the bumps; and
mounting the bumps-formed-face of said chip on predetermined position of a chip mounting substrate and bonding and fixing the chip onto the chip mounting substrate via the adhesive layer while ensuring conductivity between the chip and the chip mounting substrate.

8. A process for producing a semiconductor device, comprising the steps of:
laminating a sheet-like underfill material according to claim 3 onto a circuit face of a semiconductor wafer having bumps on its circuit face so that tops of said bumps pierce said adhesive layer;
cutting the semiconductor wafer to divide each circuit into individual chips;
peeling said base material from the surface of said adhesive layer to expose the tops of the bumps; and
mounting the bumps-formed-face of said chip on predetermined position of a chip mounting substrate and bonding and fixing the chip onto the chip mounting substrate via the adhesive layer while ensuring conductivity between the chip and the chip mounting substrate.
